(19) United States
(12) Patent Application Publication
(10) Pub. No.: US 2018/0206346 A1
(43) Pub. Date: Jul. 19, 2018

(54) PRINTED CIRCUIT BOARD MANUFACTURING METHOD AND PRINTED CIRCUIT BOARD THEREOF

(71) Applicant: Unlimiter MFA Co., Ltd., Eden Island (SC)

(72) Inventors: Kuo-Ping YANG, Taipei (TW); Yi-Yen CHIANG, Taipei (TW); Neo Bob Chih-Yung YOUNG, Taipei (TW); Lin-He CHU, Taipei (TW); Wen-Chiang WU, Taipei (TW)

(21) Appl. No.: 15/786,658

(22) Filed: Oct. 18, 2017

(30) Foreign Application Priority Data
Jan. 13, 2017 (TW) 106101297

(51) Int. Cl. H05K 3/42; H05K 3/00; H05K 3/12; H05K 3/34; H05K 1/11

(52) U.S. Cl. CPC H05K 3/426; H05K 3/0047; H05K 3/12; H05K 2203/046; H05K 3/3494; H05K 1/115; H05K 2203/045; H05K 3/3447

(57) ABSTRACT

A printed circuit board manufacturing method and a printed circuit board thereof are disclosed. The printed circuit board manufacturing method includes the steps of: providing a dielectric; performing a layout process on a surface of the dielectric; drilling the dielectric to form at least one plated through hole, wherein the at least one plated through hole has an annular ring disposed on the surface of the dielectric; and coating a solder resist on the surface of the dielectric to cover at least one part of the annular ring.

### BACKGROUND OF THE INVENTION

### 1. Field of the Invention

The present invention relates a printed circuit board manufacturing method and a printed circuit board thereof; more particularly, the present invention relates a printed circuit board manufacturing method and a printed circuit board thereof for increasing the amount of the solder paste.

### 2. Description of the Related Art

With advances in science and technology, printed circuit boards are usually manufactured for the production of electronic components. The assembly of electronic components on a printed circuit board is usually accomplished with a soldering process, such as a wave soldering process or a surface mounted process. In the prior art, a Paste-In-Hole (PIH) technology has been developed. The PIH technology is used for printing the solder paste on the plated through hole (PTH) of the printed circuit board and then inserting the electronic component into the plated through hole printed with the solder paste. At this time, most of the solder paste in the plated through hole will stick to a lead of the electronic component. After passing through a reflow oven, the solder paste will be re-melted by the heat to solder the component on the circuit board. However, requirements for solder filling PTH is 75% minimum. Thus, it is common that the amount of the solder paste is insufficient. As a result, it is necessary to increase the amount of the solder paste. However, the aforementioned methods entail additional manpower and material costs.

Therefore, it is necessary to invent a new printed circuit board manufacturing method and a printed circuit board thereof to mitigate and/or obviate the aforementioned problems.

### SUMMARY OF THE INVENTION

It is an object of the present invention to provide a printed circuit board for increasing the amount of the solder paste.

It is another object of the present invention to provide a manufacturing method applied to the abovementioned printed circuit board.

To achieve the abovementioned object, the printed circuit board of the present invention comprises a dielectric and a solder resist. The dielectric has a surface for performing a layout process and is drilled to form at least one plated through hole, wherein the at least one plated through hole has an annular ring which is disposed on the surface of the dielectric. The solder resist is coated on the surface of the dielectric to cover at least one part of the annular ring.

The printed circuit board manufacturing method of the present invention comprises the following steps: providing a dielectric; performing a layout process on a surface of the dielectric; drilling the dielectric to form at least one plated through hole, wherein the at least one plated through hole has an annular ring which is disposed on the surface of the dielectric; and coating a solder resist on the surface of the dielectric to cover at least one part of the annular ring.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1A illustrates an appearance drawing of the printed circuit board of the present invention.

FIG. 1B illustrates a part of a sectional drawing of the printed circuit board of the present invention.

FIG. 1C illustrates an appearance drawing of the metal plate of the present invention.

FIG. 2 illustrates a flowchart of the printed circuit board manufacturing method of the present invention.

FIGS. 3A-3F illustrate sectional drawings of the printed circuit board manufacturing of the present invention.

### DETAILED DESCRIPTION OF THE PREFERRED EMBODIMENT

These and other objects and advantages of the present invention will become apparent from the following description of the accompanying drawings, which disclose several embodiments of the present invention. It is to be understood that the drawings are to be used for purposes of illustration only, and not as a definition of the invention.

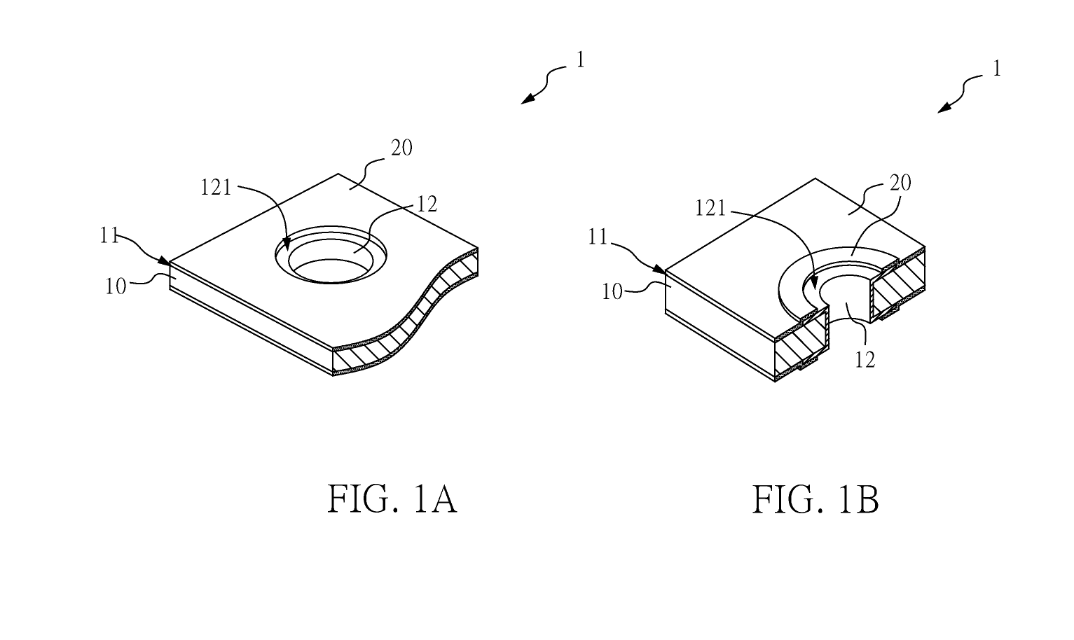

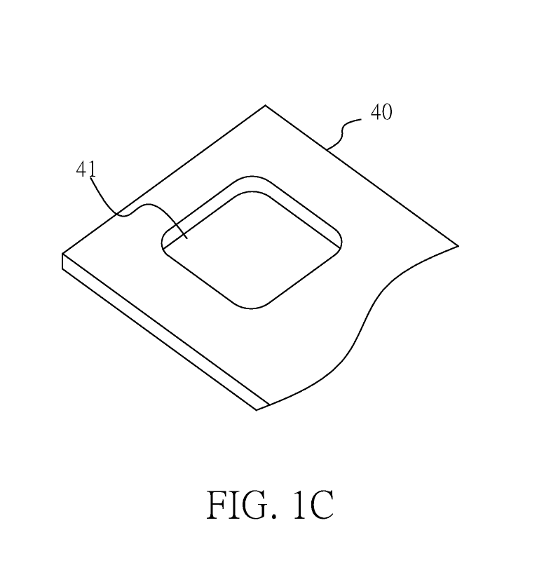

Please refer to FIGS. 1A and 1B, which illustrate an appearance drawing of the printed circuit board of the present invention and a part of a sectional drawing of the printed circuit board of the present invention.

The printed circuit board 1 of the present invention comprises a dielectric 10 which has a surface 11. The surface 11 is used for executing a layout process, such as using a subtractive transfer technology or an additive pattern transfer technology, to dispose a metal circuit on the surface 11. Since this process is not the key element of the present invention and has been widely applied by those skilled in the art related to the present invention, there is no need for further description. Then holes are drilled in the dielectric 10 according to the requirements of the layout, so as to manufacture a plated through hole 12. The plated through hole 12 has an annular ring 121 which is disposed on the surface 11 of the dielectric 10. The above-described manufacturing method is merely illustrative, and the present invention is not limited to the same process to manufacture the plated through hole 12.

After the surface circuit of the dielectric 10 is manufactured, it is necessary to deposit an insulated resin layer to protect the circuit to avoid oxidation and soldering short circuits. Thus, a solder resist 20 can be deposited on the dielectric 10 by silk screen, curtain coating, or electrostatic spraying technology. The coating range of the solder resist 20 covers the immediate area around at least one plated through hole 12; i.e., the position of the annular ring 121 of the plated through hole 12. As shown in FIG. 1B, the solder resist 20 around the plated through hole 12 may protrude slightly due to the thickness of the copper layer of the annular ring 121, but the present invention is not limited to that configuration. After the dielectric 10 cools, the dielectric 10 is delivered into an ultraviolet (UV) exposure machine to be exposed. Thus, the solder resist 20 coated on an irradiated area of the film will produce a polymerization reaction due to the ultraviolet irradiation. Then the solder resist 20 which is disposed on the non-irradiated area is removed by an aqueous solution of sodium carbonate. Finally, the dielectric 10 is baked at high temperature to completely harden the resin in the solder resist 20. In one embodiment of the present invention, the solder resist 20 can be a green paint, but the invention is not limited thereto. With the aforementioned process, the area around the plated through hole 12 can be coated with the solder resist 20.

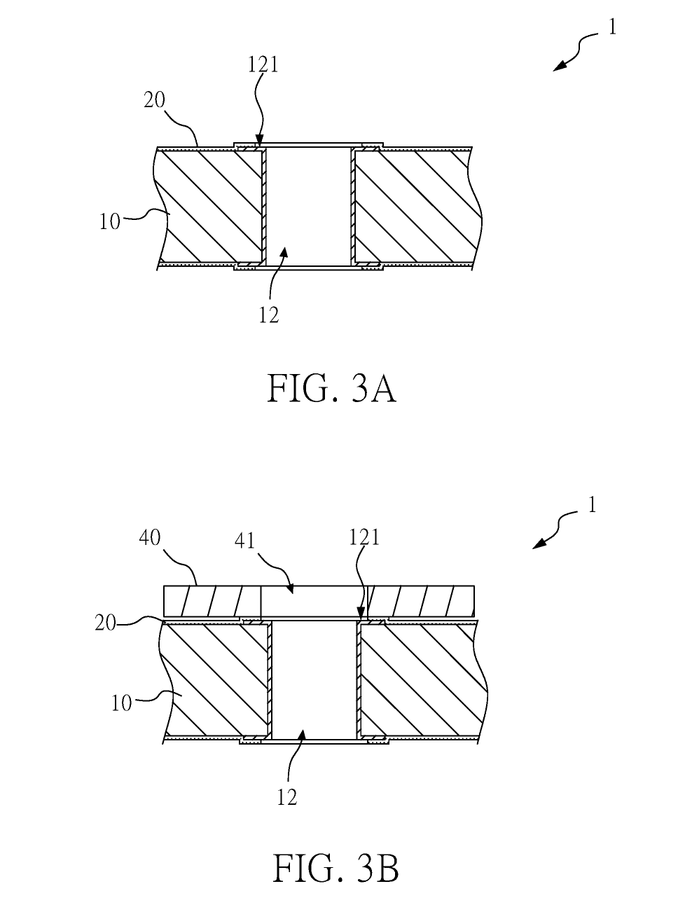

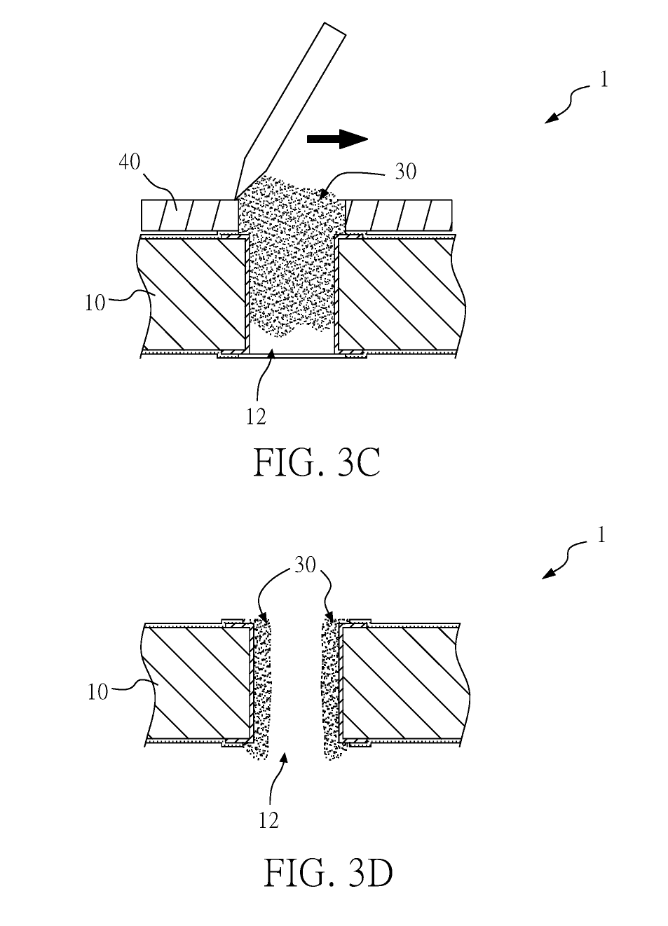

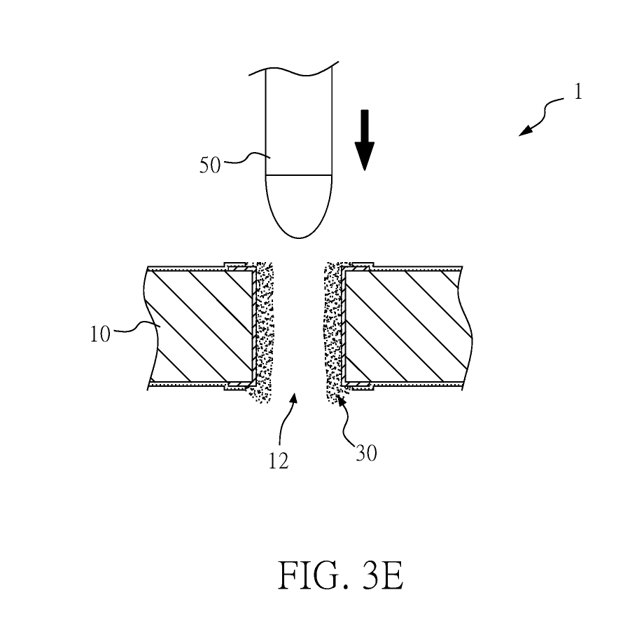

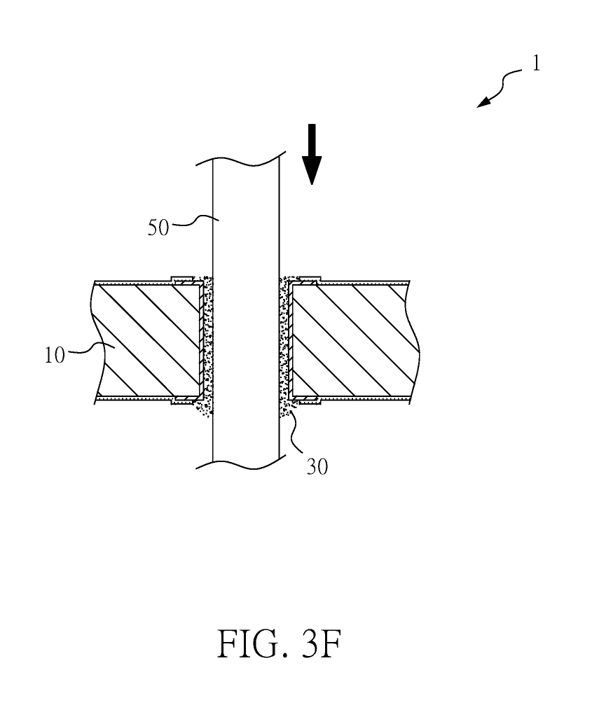

In one embodiment of present invention, a Paste-In-Hole (PIH) process, which is a surface mount technology, is used for mounting a component lead 50 (as shown in FIG. 3E). Therefore, when the component lead 50 is going to be mounted, the solder paste 30 will first be sprayed on the at least one plated through hole 12. The solder paste 30 melted after heating to solder the component lead 50 onto the dielectric 10. As shown in FIG. 1C, in the present invention, a metal plate 40 can be further disposed on the dielectric 10. FIG. 1C illustrates an appearance drawing of the metal plate of the present invention. The metal plate 40 has a rectangular opening 41, but the present invention is not limited to that shape; the opening 41 can also be round or oval. When the opening 41 of the metal plate 40 is disposed on the plated through hole 12 directly, the solder paste 30 can be easily sprayed on the metal plate 40 in a large area, such that the solder paste 30 is sprayed via the opening 41 into the plated through hole 12. In one embodiment of the present invention, since the electroplated copper layer of the plated through hole 12 may be adhered with some solder paste 30 to reduce the amount of solder paste 30 attached to the sidewall of the plated through hole 12, the solder resist 20 is coated on the annular ring 121 of the plated through hole 12 to prevent the solder paste 30 from combining with the electroplated copper layer above the annular ring 121; i.e., to prevent the solder paste 30 from attaching to the surface of the solder resist 20. When the solder resist 20 covers the area immediately around the at least one plated through hole 12, i.e., when the solder resist 20 covers a part of the annular ring 121, most of the solder paste 30 flows into the plated through hole 12 and attaches to the hole wall of the plated through hole 12. The thickness of the solder resist 20 increases the amount of solder paste 30 sprayed via the metal plate 40 so as to increase the chance of attaching to the hole wall of the plated through hole 12. Finally, the component lead 50 is mounted in the at least one plated through hole 12 and a reflow process is performed to fix the component lead 50. Thus, the assembly of the printed circuit board 1 is completed.

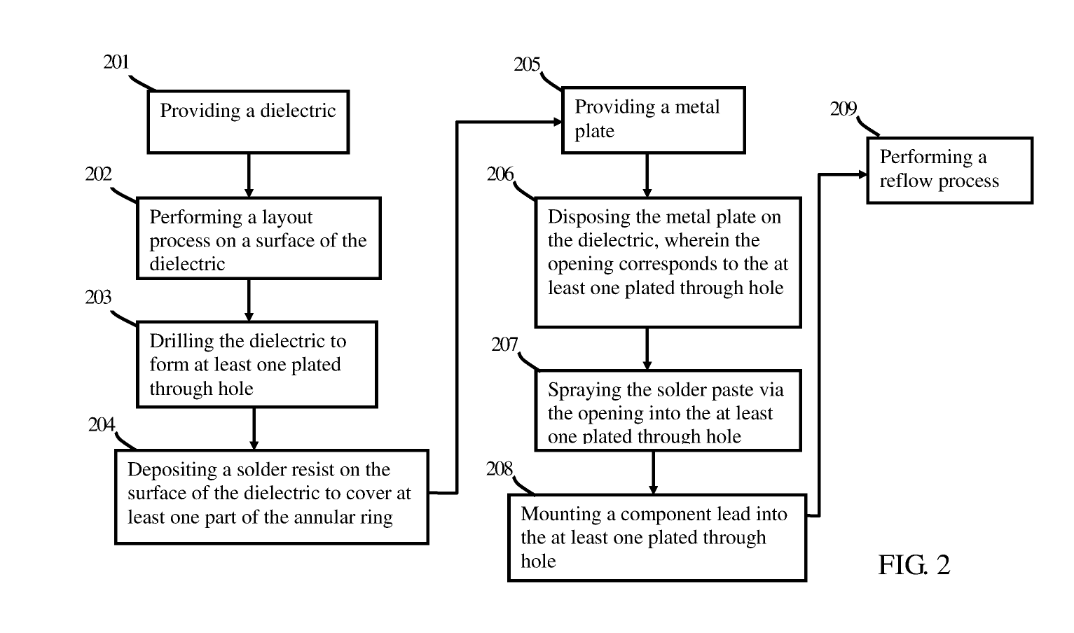

Please refer to FIG. 2, which illustrates a flowchart of the printed circuit board manufacturing method of the present invention and FIGS. 3A-3F, which illustrate sectional drawings of the printed circuit board manufacturing method of the present invention. It is to be known that, although the following description uses the abovementioned printed circuit board 1 to describe the printed circuit board manufacturing method of the present invention, the printed circuit board manufacturing method of the present invention is not limited to the structure of the printed circuit board 1.

First step 201 is performed: providing a dielectric.

First, as shown in FIG. 3A, a dielectric 10 with thermal insulation that cannot be bent is provided.

Then step 202 is executed: performing a layout process on a surface of the dielectric.

Then a layout process is performed on a surface 11 of the dielectric 10 by a subtractive transfer technology or an additive pattern transfer technology.

Then step 203 is executed: drilling the dielectric to form at least one plated through hole.

Then the dielectric 10 is drilled and a chemical solution is used for accreting the copper on the hole wall to form a through-hole circuit. A copper plating bath process is executed to make the requirement of plated through hole 12. The plated through hole 12 has an annular ring 121 which is disposed on the surface 11 of the dielectric 10.

Then step 204 is executed: depositing a solder resist on the surface of the dielectric to cover at least one part of the annular ring.

Then the solution solder resist 20 is deposited on the dielectric 10 by silk screen, curtain coating, or electrostatic spraying technology, and a pre cure process is performed. After the dielectric 10 cools, the dielectric 10 is delivered into a UV exposure machine to be exposed. Thus, the solder resist 20 coated on an irradiated area of film will remain due to a polymerization reaction caused by the ultraviolet irradiation. Then the solder resist 20 which is disposed on the non-irradiated area is removed by an aqueous solution of sodium carbonate. Finally, the dielectric 10 is baked at high temperature to completely harden the resin in the solder resist 20. In the present invention, a part of the solder resist 20 on the annular ring 121 of the plated through hole 12 will be retained so that the solder paste 20 can be close to the plated through hole 12.

Then step 205 is executed: providing a metal plate.

Then as shown in FIG. 3B, a metal plate 40 is provided. In one embodiment of the present invention, the metal plate 40 can be a steel plate, but the present invention is not limited thereto. Then the metal plate 40 is disposed at an opening 41 to fit the position of the plated through hole 12.

Then step 206 is executed: disposing the metal plate on the dielectric, wherein the opening corresponds to the at least one plated through hole.

Then the metal plate 40 is disposed on the dielectric 10 and the opening 12 corresponds to the plated through hole 12.

Then step 207 is executed: spraying the solder paste via the opening into the at least one plated through hole.

As shown in FIG. 3C to 3D, after the solder paste 30 is sprayed on the metal plate 40, the solder paste 30 will flow through the opening 41 into the plated through hole 12. Since the solder paste 30 does not adhere to the solder resist 20, most of the solder paste 30 will flow onto the hole wall of the plated through hole 12.

Then step 208 is executed: mounting a component lead into the at east one plated through hole.

As shown in FIG. 3E, the component lead 50 is mounted in at least one plated through hole 12; thus, the component lead 50 will stick to the solder paste 30 naturally.

Finally; step 209 is executed: performing a reflow process.

Finally, as shown in FIG. 3F, the reflow process is performed so as to heat the dielectric 10 together with the above component lead 50 to cause the solder paste 30 to melt. Then the component lead 50 can be fixed after the solder paste 30 cools and solidifies.

It is to be known that the order of the steps of the printed circuit board manufacturing method of the present invention is not limited to the abovementioned description and that the abovementioned order of steps can be changed as long as the object of the present invention can be achieved.

As a result, the amount of solder paste 30 in the plated through hole 12 can be increased, and there is no need for the solder paste 30 to cover the hole wall of the plated through hole 12. This design can effectively reduce costs.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope of the invention.

What is claimed is:

1. A printed circuit board manufacturing method comprising the following steps:
providing a dielectric;
performing a layout process on a surface of the dielectric;
drilling the dielectric to form at least one plated through hole, wherein the at least one plated through hole has an annular ring which is disposed on the surface of the dielectric; and
depositing a solder resist on the surface of the dielectric to cover at least one part of the annular ring.

2. The printed circuit board manufacturing method as claimed in claim further comprising the following steps:
spraying a solder paste into the at least one plated through hole;
mounting a component lead in the at least one plated through hole;
performing a reflow process.

3. The printed circuit board manufacturing method as claimed in claim 2, further comprising the following steps:
providing a metal plate, wherein the metal plate has an opening;
disposing the metal plate on the dielectric, wherein the opening corresponds to the at least one plated through hole; and
spraying the solder paste via the opening into the at least one plated through hole.

4. The printed circuit board manufacturing method as claimed in claim 1, further comprising a step of using a subtractive transfer technology or an additive pattern transfer technology for performing the layout process.

5. The printed circuit board manufacturing method as claimed in claim 1, further comprising a step of using silk screen, curtain coating, or electrostatic spraying technology to deposit the solder resist.

6. A printed circuit board, comprising:
a dielectric, having a surface for performing a layout process and drilled to form at least one plated through hole, wherein the at least one plated through hole has an annular ring which is disposed on the surface of the dielectric; and
a solder resist, coated on the surface of the dielectric to cover at least one part of the annular ring.

7. The printed circuit board as claimed in claim 6, wherein the at least one plated through hole is sprayed with a solder paste so as to mount a component lead in the at least one plated through hole and perform a reflow process.

8. The printed circuit board as claimed in claim 7, wherein the at least one plated through hole is sprayed with the solder paste via an opening of a metal plate.
